(19) United States
(12) Patent Application Publication
(10) Pub. No.: US 2026/0247674 A1
(43) Pub. Date: Aug. 20, 2026

(54) GALLIUM NITRIDE-BASED DEVICE AND PREPARATION METHOD THEREOF

(71) Applicant: NANJING UNIVERSITY, Nanjing (CN)

(72) Inventors: Feng ZHOU, Nanjing (CN); Yiteng YU, Nanjing (CN); Yu RONG, Nanjing (CN); Hai LU, Nanjing (CN); Weizong XU, Nanjing (CN); Dong ZHOU, Nanjing (CN); Fangfang REN, Nanjing (CN)

(73) Assignee: NANJING UNIVERSITY, Nanjing (CN)

(21) Appl. No.: 19/467,871

(22) Filed: Feb. 3, 2026

(30) Foreign Application Priority Data
Feb. 6, 2025 (CN) 202510131104.4

(51) Int. Cl. H10D 62/824; H10D 30/01; H10D 30/47; H10D 64/00; H10D 64/27

(52) U.S. Cl. CPC H10D 62/824; H10D 30/015; H10D 30/471; H10D 64/112; H10D 64/411

(57) ABSTRACT

A gallium nitride-based device comprises a substrate layer, a gallium nitride layer, and a barrier layer, wherein the barrier layer is provided with a gate P-type gallium nitride layer and a first gate metal layer, two sides of the gate P-type gallium nitride layer are provided with a source ohmic metal layer and a drain ohmic metal layer respectively, a source field plate metal layer and a drain field plate metal layer are connected to the source ohmic metal layer and the drain ohmic metal layer respectively, hole injection structures are disposed between the gate P-type gallium nitride layer and the drain ohmic metal layer, each hole injection structure comprises a rectangular P-type gallium nitride layer, a second gate metal layer, and an ohmic metal pillar, and the ohmic metal pillar is connected to the drain field plate metal layer.

### CROSS-REFERENCE TO RELATED APPLICATIONS

The present application claims priority to the patent application with Chinese Application No. 202510131104.4, filed on February 6, 2025, the entire contents of which are incorporated herein by reference.

### TECHNICAL FIELD

The present disclosure relates to the technical field of semiconductors, and particularly relates to a gallium nitride-based device and a preparation method thereof.

### BACKGROUND

Gallium nitride materials have excellent characteristics such as wide bandgaps, high breakdown fields, and high electron mobility, and these characteristics enable gallium nitride-based devices to operate at higher voltages and frequencies while achieving low power consumption and high efficiency. Therefore, the gallium nitride-based devices have broad application prospects in the field of high-frequency, high-power switching devices having stringent requirements on a switching speed, on-resistance, and reliability of long-term operations of the devices.

In the related art, under hard switching conditions, existing gallium nitride high-electron-mobility transistors suffer from a synergistic effect of high voltage and high current during switching. The trapping effect of carriers by trap states in device materials under off-state bias can affect channel carrier characteristics, resulting in current collapse effects, such that dynamic on-resistance of the devices increases, degrading the switching characteristics of the devices. This phenomenon is more pronounced especially under high pressure stress and high frequency environments.

Therefore, oriented to application demands for gallium nitride high-electron-mobility transistors as switching devices, there is an urgent need to solve the problems such as increased on-resistance and current collapse due to hot electron effects under hard switching conditions in such type of devices, so that trapped electrons can be released and the proper operations and service life of the devices are ensured.

### SUMMARY

The present disclosure provides a gallium nitride-based device and a preparation method thereof. It is possible to solve the problems such as increased on-resistance and current collapse under hard switching conditions due to structural defects in conventional gallium nitride-based devices of the prior art, thereby improving the reliability of the devices for long-term operations. The technical solutions are as follows:

In a first aspect, the present disclosure provides a gallium nitride-based device, including: a substrate layer, a gallium nitride layer, and a barrier layer that are arranged from bottom to top, wherein a gate P-type gallium nitride layer is provided on the barrier layer, the gate P-type gallium nitride layer is strip-shaped and extends along a first direction, a first gate metal layer is provided on the gate P-type gallium nitride layer, two sides of the gate P-type gallium nitride layer are provided with a source ohmic metal layer and a drain ohmic metal layer respectively, the source ohmic metal layer and the drain ohmic metal layer are connected to the gallium nitride layer, a source field plate metal layer is formed above and connected to the source ohmic metal layer, a drain field plate metal layer is disposed above and connected to the drain ohmic metal layer, hole injection structures are disposed between the gate P-type gallium nitride layer and the drain ohmic metal layer, each hole injection structure comprises a rectangular P-type gallium nitride layer, a second gate metal layer and an ohmic metal pillar, the rectangular P-type gallium nitride layer and the second gate metal layer are disposed on the barrier layer from bottom to top, the ohmic metal pillar passes through middle portions of both the rectangular P-type gallium nitride layer and the second gate metal layer and connects to the gallium nitride layer, a top of the ohmic metal pillar is connected to the drain field plate metal layer, a region between the barrier layer and the source field plate metal layer and a region between the barrier layer and the drain field plate metal layer are filled with a dielectric layer.

Optionally, a plurality of hole injection structures are provided and arranged at intervals along the first direction.

Optionally, in a second direction perpendicular to the first direction, rectangular P-type gallium nitride layers in at least two of the hole injection structures have different widths.

Optionally, in the second direction, a width of each second gate metal layer in the plurality of hole injection structures varies with a width of the rectangular P-type gallium nitride layer therebeneath.

Optionally, thicknesses of the second gate metal layers surrounding the ohmic metal pillars are smaller than minimum thicknesses of the rectangular P-type gallium nitride layers surrounding the ohmic metal pillars.

Optionally, the second gate metal layer and the rectangular P-type gallium nitride layer each have an internal hole in a middle portion thereof for the ohmic metal pillar to pass through, and a size of the internal hole in the second gate metal layer is smaller than or equal to that of the internal hole in the rectangular P-type gallium nitride layer.

Optionally, the ohmic metal pillar, the source ohmic metal layer, and the drain ohmic metal layer have equal heights.

Optionally, a cross-sectional profile of the ohmic metal pillar is square, circular, or irregular.

Optionally, vias are etched in the dielectric layer located between the source ohmic metal layer and the source field plate metal layer, between the drain ohmic metal layer and the drain field plate metal layer, and between the ohmic metal pillar and the drain field plate metal layer, wherein connections between the source ohmic metal layer and the source field plate metal layer, between the drain ohmic metal layer and the drain field plate metal layer, and between the ohmic metal pillar and the drain field plate metal layer are formed by metal deposited in the vias.

In a second aspect, the present disclosure further provides a preparation method for manufacturing the gallium nitride-based device according to the first aspect, including:

Step 1: growing a substrate layer, a gallium nitride layer, a barrier layer, and a P-type gallium nitride layer on an epitaxial wafer sequentially from bottom to top, and etching the P-type gallium nitride layer in non-patterned regions to form a gate P-type gallium nitride layer and a plurality of rectangular P-type gallium nitride layers;

Step 2: depositing a dielectric layer on the entire barrier layer, etching to thin the rectangular P-type gallium nitride layers, and etching the dielectric layer and the barrier layer at middle portions of the rectangular P-type gallium nitride layers as well as a source region and a drain region at the same time;

Step 3: depositing a source ohmic metal layer and a drain ohmic metal layer in the source region and the drain region respectively, and depositing an ohmic metal pillar in the middle of each rectangular P-type gallium nitride layer;

Step 4: etching the dielectric layer above the gate P-type gallium nitride layer and depositing the first gate metal layer on the gate P-type gallium nitride layer, etching the dielectric layer above the rectangular P-type gallium nitride layers and depositing a second gate metal layer surrounding the ohmic metal pillar;

Step 5: depositing the dielectric layer again, etching the dielectric layer above the source ohmic metal layer, the drain ohmic metal layer and the ohmic metal pillars to form vias corresponding to the source ohmic metal layer, the drain ohmic metal layer and the ohmic metal pillars respectively, and depositing metal in the vias;

Step 6: depositing the dielectric layer again, etching the dielectric layer and depositing a source field plate metal layer connected to the source ohmic metal layer and a drain field plate metal layer connected to the ohmic metal pillar and the drain ohmic metal layer.

Beneficial effects achieved by the technical solutions provided by the present disclosure at least include:

Compared to the conventional gallium nitride high-electron-mobility transistor structure, the hole injection structures consisting of rectangular P-type gallium nitride layers, second gate metal layers, and ohmic metal pillars are introduced into the regions between the gate P-type gallium nitride layer as the gate structures and the drain ohmic metal layer as the drain structures of the gallium nitride-based device provided by embodiments of the present disclosure. When bias voltage is applied to drains, holes are injected into the barrier layer and the gallium nitride layer through the rectangular P-type gallium nitride layers, and the injected holes can effectively release electrons trapped by traps near the drains through carrier recombination and other approaches, thereby solving the problems of current collapse and dynamic on-resistance degradation of the device. Further, bottom surfaces of the ohmic metal pillars surrounding the rectangular P-type gallium nitride layers and the second gate metal layers are in contact with the gallium nitride layer, such that a gate-to-drain distance of the device is reduced, which balances the problem of current reduction caused by disposing the rectangular P-type gallium nitride layers on a side close to the drains of the device to some extend and attenuates effects of the rectangular P-type gallium nitride layers on two-dimensional electron gas concentration in channels of the device. In addition, the device is simple to manufacture, the hole injection structures grow simultaneously with gate, source, and drain structures of the device, so that compatibility with existing processes can be achieved, the problems like current collapse and dynamic on-resistance degradation caused by hot electron effects under hard switching conditions are solved on the premise of not affecting the normal operations of the device, and the reliability of the device for long-term operations is effectively improved.

### BRIEF DESCRIPTION OF THE DRAWINGS

To describe the technical solutions in embodiments of the present disclosure more clearly, the following briefly describes the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a schematic diagram of a structure of a conventional gallium nitride-based device;

FIG. 2 is a schematic diagram of a structure on which a substrate layer, a gallium nitride layer, a barrier layer, a gate P-type gallium nitride layer, and a rectangular P-type gallium nitride layer of a gallium nitride-based device provided in embodiments of the present disclosure are prepared;

FIG. 3 is a schematic diagram of a structure after etching the rectangular P-type gallium nitride layer shown in FIG. 2, a source region and a drain region of the gallium nitride-based device according to the embodiments of the present disclosure;

FIG. 4 is a schematic diagram of a structure after preparing a source ohmic metal layer, a drain ohmic metal layer, and an ohmic metal pillar on the structure shown in FIG. 3;

FIG. 5 is a schematic diagram of a structure after preparing a first gate metal layer and a second gate metal layer on the structure shown in FIG. 4;

FIG. 6 is a schematic diagram of a structure after preparing vias on the structure shown in FIG. 5;

FIG. 7 is a schematic diagram of a structure of a gallium nitride-based device provided in embodiments of the present disclosure from one perspective;

FIG. 8 is a schematic diagram of a structure of a gallium nitride-based device provided in embodiments of the present disclosure from another perspective;

FIG. 9 is a flow chart of a preparation method of a gallium nitride-based device provided in embodiments of the present disclosure.

In the figures: 1-substrate layer; 2-gallium nitride layer; 3-barrier layer; 4-gate P-type gallium nitride layer; 5-source ohmic metal layer; 6-drain ohmic metal layer; 7-hole injection structure; 8-dielectric layer; 9-via; 41-first gate metal layer; 51-source field plate metal layer; 61-drain field plate metal layer; 71-rectangular P-type gallium nitride layer; 72-second gate metal layer; 73-ohmic metal pillar; a-conventional substrate layer; b-conventional gallium nitride layer; c-conventional barrier layer; d-gate; e-drain.

### DETAILED DESCRIPTION OF THE EMBODIMENTS

To make the objectives, technical solutions, and advantages of the present disclosure more clear, implementations of the present disclosure will be further described in detail below with reference to the accompanying drawings.

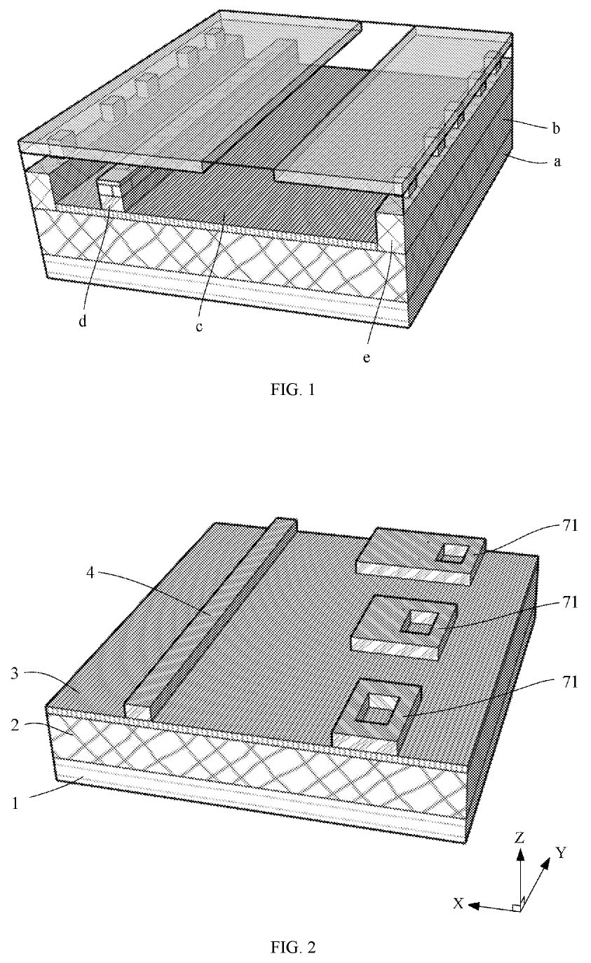

FIG. 1 is a schematic diagram of a structure of a conventional gallium nitride-based device. As shown in FIG. 1, a structure of an existing gallium nitride-based device generally includes a conventional substrate layer a, a conventional gallium nitride layer b, and a conventional barrier layer c sequentially arranged from bottom to top. A gate region above the conventional barrier layer c is provided with a strip-shaped p-type gallium nitride layer to form an enhanced gate structure. For existing gallium nitride-based devices, when the devices are operated under hard switching conditions, the devices are subjected to a combined action of high voltage and high current, causing trapping of injected hot electrons by traps on a surface of the conventional barrier layer c and traps in a buffer layer (conventional gallium nitride layer b) in an off-state. Traps here refer to crystal defect centers in semiconductors capable of trapping electrons or holes. For gallium nitride-based materials, traps in a concentration are present both on the surface of the conventional barrier layer c and in the conventional gallium nitride layer b, causing a trapping effect on carriers. The devices are subjected to a combined action of high voltage and high current under hard switching conditions, a region between a gate d and a drain e of the device generates an electron-hole pair. The electrons move to one side of the drain e under the traction of a source-drain lateral electric field, and holes move in an opposite direction. In this process, the electrons are easily trapped by traps on the surface of the conventional barrier layer c and traps in the conventional gallium nitride layer b, thereby generating a depletion effect on the two-dimensional electron gas in channels, eventually resulting in current collapse and dynamic on-resistance degradation, and further seriously affecting the reliability of the device for long-term operations.

As shown in FIGS. 2-8, a gallium nitride-based device provided in embodiments of the present disclosure includes a substrate layer 1, a gallium nitride layer 2, and a barrier layer 3 sequentially disposed from bottom to top. A gate P-type gallium nitride layer 4 in a strip-shaped and extending in a first direction Y is disposed on the barrier layer 3, and a first gate metal layer 41 is disposed on the gate P-type gallium nitride layer 4. Two sides of the gate P-type gallium nitride layer 4 are provided with a source ohmic metal layer 5 and a drain ohmic metal layer 6 respectively, and both the source ohmic metal layer 5 and the drain ohmic metal layer 6 are connected to the gallium nitride layer 2. A source field plate metal layer 51 is disposed above and connects to the source ohmic metal layer 5, and a drain field plate metal layer 61 is disposed above and connects to the drain ohmic metal layer 6. A plurality of hole injection structures 7 are disposed between the gate P-type gallium nitride layer 4 and the drain ohmic metal layer 6. Each hole injection structure 7 includes a rectangular P-type gallium nitride layer 71 and a second gate metal layer 72 disposed on the barrier layer 3 from bottom to top, as well as an ohmic metal pillar 73 passes through middle portions of the rectangular P-type gallium nitride layer 71 and the second gate metal layer 72. The ohmic metal pillar 73 is connected to the gallium nitride layer 2. A top of the ohmic metal pillar 73 is connected to the drain field plate metal layer 61. A region between the barrier layer 3 and the source field plate metal layer 51 and a region between the barrier layer 3 and the drain field plate metal layer 61 are filled with a dielectric layer 8.

In embodiments of the present disclosure, when the gallium nitride-based device is manufactured, with reference to FIG. 2, a silicon substrate layer 1 having a thickness of 0.65 mm, a gallium nitride layer 2 having a thickness of 2 μm, a barrier layer 3 having a thickness of 20 nm, and a P-type gallium nitride layer having a thickness of 100 nm are grown on an epitaxial wafer sequentially from bottom to top. The P-type gallium nitride layer in non-patterned regions is then etched by an inductively coupled plasma dry etching method to form a plurality of rectangular P-type gallium nitride layers 71 and a gate P-type gallium nitride layer 4 in a long-strip-shaped and extending along the first direction Y. The rectangular P-type gallium nitride layers 71 are located at a side of the gate P-type gallium nitride layer 4 near a drain of the device. It should be noted that in the embodiments of the present invention, the first direction Y is an extending direction of the gate P-type gallium nitride layer 4 in a long-strip-shaped on a straight line, i.e., an arrangement direction when a plurality of rectangular P-type gallium nitride layers 71 are disposed at intervals in FIG. 2.

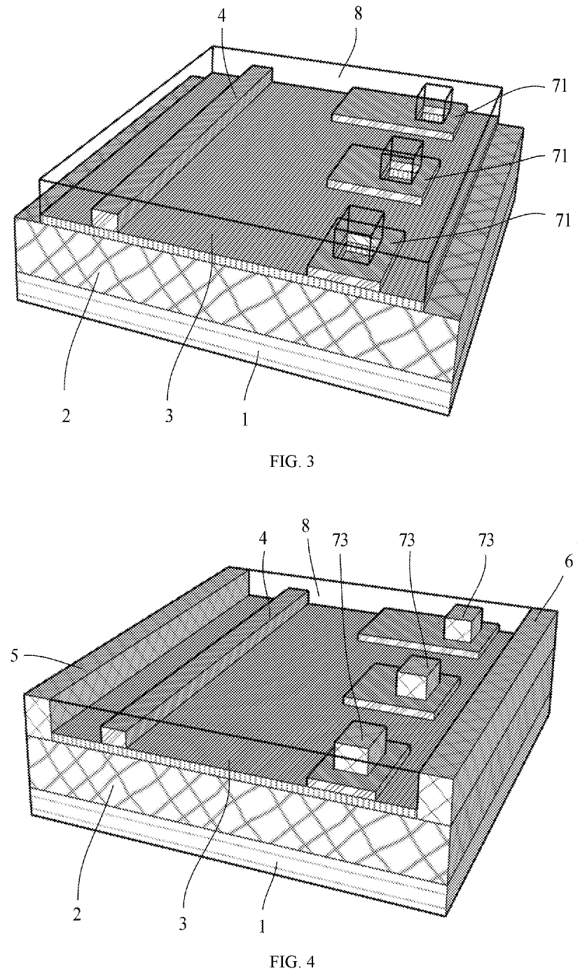

Then, with reference to FIG. 3, a dielectric layer 8 is grown on the entire epitaxial wafer by a plasma enhanced chemical vapor deposition method, and the rectangular P-type gallium nitride layers 71 are thinned by etching with the inductively coupled plasma dry etching method. Then, the dielectric layer 8 is grown again, the dielectric layer 8 and the barrier layer 3 at the middle portions of rectangular P-type gallium nitride layers 71, a source region and a drain region are etched by the inductively coupled plasma dry etching method so that each rectangular P-type gallium nitride layer 71 can be processed into a structure having opening in communication with the gallium nitride layer 2 at the middle portion and having a rectangular annular shape as a whole. The source region and the drain region refer to preset regions located at both sides of the gate P-type gallium nitride layer 4 for disposing the source structure and drain structure of the device respectively.

Then, with reference to FIG. 4, metal layers consists of Ti/Al (300 nm/700 nm) are sequentially deposited in the source region and the drain region obtained in FIG. 3 and opening regions at the middle portions of the rectangular P-type gallium nitride layers 71 to form the source ohmic metal layer 5 and the drain ohmic metal layer 6 in the source region and the drain region respectively, and form one ohmic metal pillar 73 in each opening region. The source ohmic metal layer 5, the drain ohmic metal layer 6, and each ohmic metal pillar 73 are all in contact with a top surface of the gallium nitride layer 2. The foregoing "sequentially" means that when the ohmic metal layer structures are deposited, a titanium metal layer having a thickness of 300 nm is deposited first, an aluminum metal layer having a thickness of 700 nm is then deposited, and the following similar expressions have similar meanings.

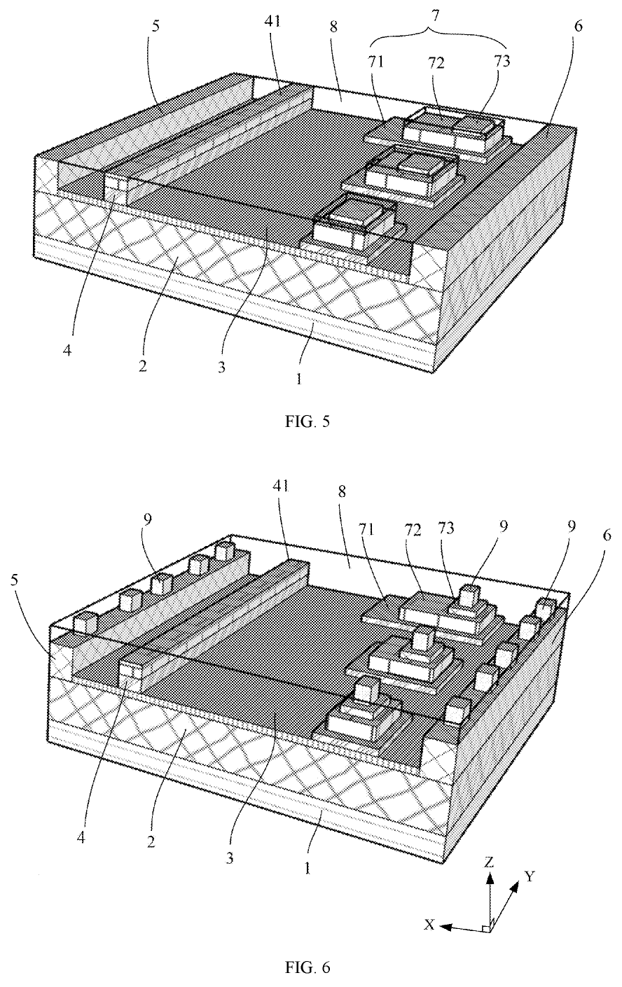

Then, with reference to FIG. 5, the dielectric layer 8 is grown again on an entire epitaxial wafer, the dielectric layer 8 above the gate P-type gallium nitride layer 4 and the rectangular P-type gallium nitride layers 71 are etched by the inductively coupled plasma dry etching method and a photoetching stripping method, and gate metal consists of Ni/Al (300 nm/500 nm) is sequentially deposited to form a first gate metal layer 41 also in a strip shape and the second gate metal layer 72. The second gate metal layer 72 is of a structure in a rectangular annular shape (namely, a frame-within-a-frame structure or a rectangular ring-shaped structure) and surrounds the ohmic metal pillar 73.

Then, with reference to FIG. 6, the dielectric layer 8 is grown again on an entire epitaxial wafer, the dielectric layer 8 above the source ohmic metal layer 5, the drain ohmic metal layer 6 and the ohmic metal pillar 73 are etched by the inductively coupled plasma dry etching method and the photoetching stripping method to form a plurality of vias 9 which are corresponding to the source ohmic metal layer 5, the drain ohmic metal layer 6 and the ohmic metal pillar 73 respectively. Tungsten metal is deposited in the vias 9 to form a via metal plug connected to a field plate structure on a top of the device. Exemplarily, in another possible implementation, the ohmic metal pillar 73 can also be deposited directly upward by a certain height when the ohmic metal pillar 73 is prepared, with the deposition height as the height of the vias 9 etched on the source ohmic metal layer 5 and the drain ohmic metal layer 6 in FIG. 6 for direct connection to the drain field plate metal layer 61. At this situation, etching of the vias 9 and metal deposition above the ohmic metal pillar 73 can be avoided.

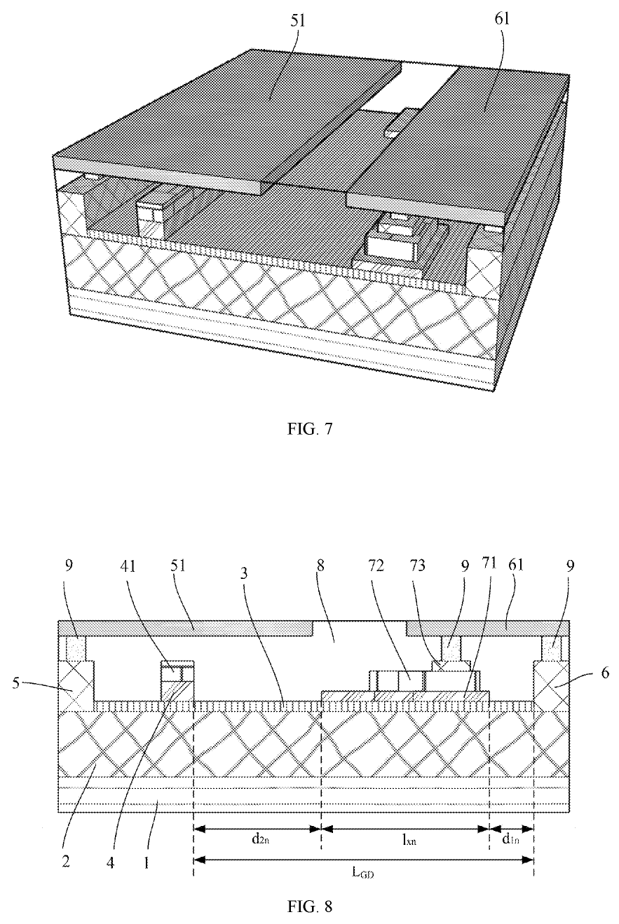

Finally, with reference to FIG. 7 and FIG. 8, the dielectric layer 8 is deposited again, the dielectric layer 8 above the vias 9 is etched by the photoetching stripping method, and the source field plate metal layer 51 and the drain field plate metal layer 61 are deposited above the vias 9 to complete the preparation of a transistor core portion of the gallium nitride-based device. Specifically, the source ohmic metal layer 5 is connected to the source field plate metal layer 51 via the tungsten metal deposited in the vias 9 on the source ohmic metal layer 5. Each ohmic metal pillar 73 and the drain ohmic metal layer 6 are respectively connected to the drain field plate metal layer 61 via the tungsten metal deposited in the vias 9 above the ohmic metal pillar 73 and the drain ohmic metal layer 6.

Exemplarily, in embodiments of the present disclosure, the gate P-type gallium nitride layer 4 and the first gate metal layer 41 arranged on the gate P-type gallium nitride layer form a gate of the gallium nitride-based device. The source ohmic metal layer 5, the vias 9 on the source ohmic metal layer 5, and the source field plate metal layer 51 form a source of the gallium nitride-based device. The drain ohmic metal layer 6, the vias 9 on the drain ohmic metal layer, and the drain field plate metal layer 61 form a drain of the gallium nitride-based device.

Compared to the conventional gallium nitride high-electron-mobility transistor structure, in the gallium nitride-based device of this embodiment, a plurality of hole injection structures 7 are provided between the gate P-type gallium nitride layer 4 acted as a gate structure and the drain ohmic metal layer 6 acted as a drain structure, and each hole injection structure 7 consists of a rectangular P-type gallium nitride layer 71, a second gate metal layer 72, and an ohmic metal pillar 73. When bias voltage is applied to the drain, holes are injected into the barrier layer 3 and the gallium nitride layer 2 through the rectangular P-type gallium nitride layers 71, and the injected holes can effectively release electrons trapped by traps near the drains through carrier recombination and other approaches, thereby solving the problems of current collapse and dynamic on-resistance degradation of the device. Further, bottom surfaces of the ohmic metal pillars 73 surrounding the rectangular P-type gallium nitride layers 71 and the second gate metal layers 72 are in contact with the gallium nitride layer 2, such that a gate-to-drain distance of the device is reduced, which balances the problem of current reduction caused by disposing the rectangular P-type gallium nitride layers 71 on a side close to the drain of the device to some extend and attenuates effects of the rectangular P-type gallium nitride layers on two-dimensional electron gas concentration in channels of the device. In addition, the device is simple to manufacture, the hole injection structures 7 grow simultaneously with gate, source, and drain structures of the device, so that compatibility with existing processes can be achieved, the problems like current collapse and dynamic on-resistance degradation caused by hot electron effects under hard switching conditions are solved on the premise of not affecting the normal operations of the device, and the reliability of the device for long-term operations is effectively improved.

Optionally, a plurality of hole injection structures 7 are provided and the hole injection structures 7 are arranged at intervals along the first direction Y. Exemplarily, a total number of the rectangular P-type gallium nitride layers 71 is n, n ≥ 1. Along the first direction Y, an outer profile of the n-th rectangular P-type gallium nitride layer 71 has a length of l_{yn}, with a value range of 4≤ l_{yn}≤50 μm. Along the second direction X, the outer profile of the n-th rectangular P-type gallium nitride layer 71 has a width of lₓₙ, with a value range of 4≤ lₓₙ≤16 μm. A length and width of an internal hole of each rectangular P-type gallium nitride layer 71 distributed along the first direction Y remain consistent, and the internal hole has a length of f, with a value range of 2≤ f ≤40μm, and a width of g, with a value range of 2≤ g ≤5 μm.

In embodiments of the present disclosure, a thickness of the rectangular P-type gallium nitride layer 71 is 20 nm, which is smaller than a thickness of the gate P-type gallium nitride layer 4. There are three rectangular P-type gallium nitride layers 71. A bleed channel is formed by a vertical region consisted of the rectangular P-type gallium nitride layer 71, the barrier layer 3 and the gallium nitride layer 2 under the rectangular P-type gallium nitride layer 71 to ensure the release efficiency of electrons trapped by traps. In other possible implementations, depending on the overall length of the device in the first direction Y, more rectangular P-type gallium nitride layers 71 may also be provided to form the plurality of hole injection structures 7. The specific number of the rectangular P-type gallium nitride layers 71 is not limited in the embodiments of the present disclosure. The outer profiles of three rectangular P-type gallium nitride layers 71 disposed along the first direction Y have a length l_{y1}=l_{y2}=l_{y3}=8 μm and a width in the second direction X of lₓ₁=5 μm, lₓ₂=7 μm, lₓ₃=9 μm. The internal holes in the three rectangular P-type gallium nitride layers 71 distributed along the first direction Y have a length f of 4 μm and a width g of 2 μm.

In some embodiments, a shape of the internal hole of the rectangular P-type gallium nitride layer 71 is mated with a shape of the side edge of the ohmic metal pillar 73, which is not limited to a rectangle. In other possible implementations, the shape may also be a square, a circle, or other irregular shapes, for example, various polygons. The use of the structure of the rectangular P-type gallium nitride layer 71 in a rectangular annular shape as a whole, as well as internally surrounded rectangular columnar ohmic metal pillar 73 is the selection considering standardized deposition and etching processes and ensures processing efficiency and accuracy.

Optionally, in a second direction X perpendicular to the first direction Y, rectangular P-type gallium nitride layers 71 in at least two of the hole injection structures 7 have different widths. Further, along the second direction X, in the plurality of the hole injection structures 7, the width of each second gate metal layer 72 varies with the width of the rectangular P-type gallium nitride layer 71 therebeneath. Exemplarily, in embodiments of the present disclosure, the rectangular P-type gallium nitride layers 71 facilitate hole injection, thereby reducing carrier trapping and mitigating current collapse.The larger the width of the rectangular P-type gallium nitride layer 71 along the second direction X, the better. The excessively narrow rectangular P-type gallium nitride layer 71 has poor hole injecting ability, the electrons trapped by the traps cannot be well released. It is preferable that the left side of the rectangular P-type gallium nitride layer 71 is very close to the gate P-type gallium nitride layer 4, the right side is very close to the drain ohmic metal layer 6, and the length and width of each rectangular P-type gallium nitride layer 71 distributed along the first direction Y remain consistent. However, from the perspective of the influence of the rectangular P-type gallium nitride layers 71 on the current capability of the device itself, although the rectangular P-type gallium nitride layers 71 are thinned by etching, and the ohmic metal pillars 73 at the middle portions allow the on-state current of the device to pass through, but due to the presence of a heterogeneous pn-junction barrier of the rectangular P-type gallium nitride layers 71-barrier layer 3/gallium nitride layer 2, the rectangular P-type gallium nitride layers 71 still cause some depletion of two-dimensional electron gas in the channels below them, resulting in a reduction of the concentration of the two-dimensional electron gas. If the multiple the rectangular P-type gallium nitride layers 71 all adopt the design with the highest hole injection capability, a certain negative effect on the on-current capability of the device may be caused. Therefore, embodiments of the present disclosure adopt the design in which the rectangular P-type gallium nitride layers 71 widen gradually in the second direction X, while the device reliability problems of current collapse and dynamic on-resistance degradation can be better solved with the rectangular P-type gallium nitride layers 71, the influence of the rectangular P-type gallium nitride layers 71 on the performance such as the output current capability of the device can be balanced, thereby ensuring the performance and reliability of the device for long-term operations. Further, since the rectangular P-type gallium nitride layers 71 need to be controlled by the second gate metal layers 72 to achieve the effect of injecting holes to release electrons trapped by the traps on the device surface and in the buffer layer under hard switching conditions. Therefore, as the widths of the rectangular P-type gallium nitride layers 71 increase, certain widening of the second gate metal layers 72 is also required, thereby better controlling the rectangular P-type gallium nitride layers 71.

It should be noted that in other possible implementations, when the plurality of rectangular P-type gallium nitride layers 71 are arranged along the first direction Y, the widths of the plurality of rectangular P-type gallium nitride layers 71 in the second direction X can take other arrangement forms, such as lₓ₁=7 μm, lₓ₂=5 μm, lₓ₃=9 μm, or lₓ₁=5 μm, lₓ₂=5 μm, lₓ₃=7 μm. As long as it is satisfied that there is a difference in the widths of the at least two rectangular P-type gallium nitride layers 71 in the first direction Y. The embodiments of the present disclosure are not limited to the specific size length and the arrangement order according to the length.

Further, in other possible implementations, during the arrangement along the first direction Y, the lengths of the plurality of rectangular P-type gallium nitride layers 71 in the first direction Y and the spacing between adjacent rectangular P-type gallium nitride layers 71 may be different. Accordingly, the length and width of the second gate metal layer 72 may be adaptively increased or decreased according to the length and width of the rectangular P-type gallium nitride layer 71 therebeneath, with a variable quantity consistent with the variable quantity of the length and width of the rectangular P-type gallium nitride layer 71.

Optionally, a distance between the right side of the n-th rectangular P-type gallium nitride layer 71 and the left side of the drain ohmic metal layer 6 is d₁ₙ, with a value range of 2≤ d₁ₙ≤5 μm. A distance between the left side of the n-th rectangular P-type gallium nitride layer 71 and the right side of the gate P-type gallium nitride layer 4 is d₂ₙ, with a value range of 1≤ d₂ₙ≤24 μm. The distance between the left side of the rectangular P-type gallium nitride layer 71 and the right side of the gate P-type gallium nitride layer 4 as well as the distance between the right side of the rectangular P-type gallium nitride layer 71 and the left side of the drain ohmic metal layer 6 satisfy the relationship of L_{GD}=lₓₙ+d₁ₙ+d₂ₙ, where L_{GD} is the distance between the right side of the gate P-type gallium nitride layer 4 and the left side of the drain ohmic metal layer 6, with a value range of 7≤ L_{GD}≤30 μm. If the total number n of the rectangular P-type gallium nitride layers 71 is n>1, the spacing between the m-th rectangular P-type gallium nitride layer 71 and the (m+1)-th rectangular P-type gallium nitride layer 71 along the first direction Y is d_{m,m+1}, where 1≤ m ≤n-1, 2≤d_{m,m+1}≤50 μm. Various dimensions of the rectangular P-type gallium nitride layer 71 in the first direction Y satisfy the relationship Wₒ= ∑l_{yn}+ ∑d_{m,m+1}, where Wₒ is the length of the source ohmic metal layer 5 or the drain ohmic metal layer 6 in the first direction Y, with a value range of 10≤ Wₒ≤500 μm.

Preferably, the distances between the right sides of the three rectangular P-type gallium nitride layers 71 distributed along the first direction Y and the left sides of the drain ohmic metal layer 6 are d₁₁=d₁₂=d₁₃=2 μm, respectively. The distances between the left side of the rectangular P-type gallium nitride layer 71 and the right side of the gate P-type gallium nitride layer 4 as well as between the right side of the rectangular P-type gallium nitride layer 71 and the left side of the drain ohmic metal layer 6 satisfy the relationship of L_{GD}= lₓₙ+d₁ₙ+d₂ₙ=20 μm, where L_{GD} is the spacing between the right side of the gate P-type gallium nitride layer 4 and the left side of the drain ohmic metal layer 6. Therefore, the distances between the left sides of the three rectangular P-type gallium nitride layers 71 distributed along the first direction Y and the right side of the gate P-type gallium nitride layer 4 are d₂₁=13 μm, d₂₂=11 μm and d₂₃=9 μm, respectively. The distances of the m-th rectangular P-type gallium nitride layer 71 and the (m+1)-th rectangular P-type gallium nitride layer 71 distributed along the first direction Y is d_{1,2}=d_{2,3}=8 μm, respectively. Various dimensions of the rectangular P-type gallium nitride layer 71 in the first direction Y satisfy the relationship Wₒ= ∑l_{yn}+∑d_{m,m+1}=40 μm, and Wₒ is the length of the source ohmic metal layer 5 or the drain ohmic metal layer 6 in the first direction Y.

Optionally, in the first direction Y, the outer profile of the n-th second gate metal layer 72 has a length of cₙ, with a value range of 3≤ cₙ≤49 μm; in the second direction X, the outer profile of the n-th second gate metal layer has a width of eₙ, with a value range of 3≤ eₙ≤15 μm. The length and width of the internal hole of each second gate metal layer 72 distributed along the first direction Y remain consistent, the length is f, with a value range of 2≤ f ≤40μm, and the width is g, with a value range of 2≤ g ≤5 μm.

Preferably, the thickness of the second gate metal layer 72 is equal to the thickness of the first gate metal layer 41. The outer profiles of the three second gate metal layers 72 distributed along the first direction Y have the length of c₁=c₂=c₃=6 μm and the widths of e₁=3μm, e₂=5μm, e₃=7μm, respectively. The internal holes of the three second gate metal layers 72 distributed along the first direction Y have the length of f =4 μm and the width of g =2 μm. In the first direction Y, the spacing of two adjacent second gate metal layers 72 is 10 μm.

Optionally, the thickness of the second gate metal layer 72 surrounding the ohmic metal pillar 73 is smaller than the minimum thickness of the rectangular P-type gallium nitride layer 71 surrounding the ohmic metal pillar 73. Exemplarily, in embodiments of the present disclosure, the rectangular P-type gallium nitride layer 71 need to laterally wrap the ohmic metal pillar 73 with the thinnest wrapping thickness of 1 μm. The front/back side faces of the three ohmic metal pillars 73 distributed along the first direction Y have the same thickness t_{y1n} wrapped by the rectangular P-type gallium nitride layers 71, t_{y1n}= (l_{yn}-l_{oy})/2, and t_{y11}=t_{y12}=t_{y13}=2 μm. The left/right side faces (in the second direction X) of the three ohmic metal pillars 73 distributed along the first direction Y wrapped by the rectangular P-type gallium nitride layers 71 have the thicknesses tₗ₁₁=1 μm, tₗ₁₂=3 μm, tₗ₁₃=6 μm, tᵣ₁₁=tᵣ₁₂=tᵣ₁₃=1 μm. The second gate metal layer 72 need to laterally wrap the ohmic metal pillar 73 with the thinnest wrapping thickness of 0.5 μm. The front/back side faces of the three ohmic metal pillars 73 distributed along the first direction Y have the same thickness t_{y2n} wrapped by the second gate metal layers 72, t_{y2n}= (cₙ-l_{oy})/2, and t_{y21}=t_{y22}=t_{y33}=1 μm. The left/right side faces (in the second direction X) of the three ohmic metal pillars 73 distributed along the first direction Y wrapped by the second gate metal layers 72 have the thicknesses tₗ₂ₙ=0.5 μm, tₗ₂ₙ=1.5 μm, tₗ₂ₙ=2.5 μm, tᵣ₂₁=tᵣ₂₂=tᵣ₂₃=0.5 μm.

Optionally, the second gate metal layer 72 and the rectangular P-type gallium nitride layer 71 each have an internal hole in a middle portion thereof for the ohmic metal pillar 73 to pass through, and a size of the internal hole in the second gate metal layer 72 is smaller than or equal to that of the internal hole in the rectangular P-type gallium nitride layer 71. Exemplarily, in embodiments of the present disclosure, the internal hole of the rectangular P-type gallium nitride layer 71 and the internal hole of the second gate metal layer 72 are ideally identical in length and width, and the length/width of the ohmic metal pillar 73 at different heights are also consistent. However, in actual preparation of the device, deposition of the entire ohmic metal pillars 73 is completed before etching of the second gate metal layers 72. When the dielectric layer 8 in regions corresponding to the rectangular P-type gallium nitride layers 71 are etched for making preparation for depositing the second gate metal layers 72, it is difficult to guarantee that the ohmic metal pillars 73 are not etched in an actual process, that is, making the internal hole of the rectangular P-type gallium nitride layer 71 and the internal hole of the second gate metal layer 72 exactly the same in length and width adds additional difficulties to the etching process. Thus, in the actual device preparation process, there is a situation that a small portion is also etched away from peripheries of the ohmic metal pillar 73 by one turn, after which the second gate metal layer 72 are deposited, thus making the length/width of the ohmic metal pillar 73 at different heights dependent on the length/width of the internal hole wrapping the outer layers (i.e. the rectangular P-type gallium nitride layer 71 or the second gate metal layer 72). The preparation of the second gate metal layers 72 is carried out by this process, which does not add additional difficulties to the process, also can guarantee good control over the rectangular P-type gallium nitride layers 71 below the second gate metal layers by the second gate metal layers 72, and improves the preparation efficiency.

Optionally, the side face of the ohmic metal pillar 73 is tightly wrapped by the barrier layer 3, the rectangular P-type gallium nitride layer 71, and the second gate metal layer 72 sequentially from bottom to top. The length/width of the ohmic metal pillar 73 at different heights depend on the lengths/widths of the holes on the inner sides wrapping the outer layers. The portion of the ohmic metal pillar 73 wrapped by the rectangular P-type gallium nitride layer 71 has a length of l_{oy1}, with a value range of 2≤ l_{oy1}≤40 μm, and a width of lₒₓ₁, with a value range of 2≤ lₒₓ₁≤5 μm. The portion of the ohmic metal pillar 73 wrapped by the second gate metal layer 72 has a length of l_{oy2}, with a value range of 2≤ l_{oy2}≤40 μm, and a width of lₒₓ₂, with a value range of 2≤lₒₓ₂≤5 μm.

Preferably, the ohmic metal pillar 73, the source ohmic metal layer 5, and the drain ohmic metal layer 6 have equal heights. Exemplarily, in embodiments of the present disclosure, the shape and size of each ohmic metal pillar 73 distributed along the first direction Y at the same height remain consistent, and the center of a top surface of each ohmic metal pillar 73 is located on the same straight line parallel to the first direction Y, facilitating structure preparation of subsequent connection of the source ohmic metal layer 5 and the drain ohmic metal layer 6 with the top field plate structure. The portion of the ohmic metal pillar 73 surrounded by the rectangular P-type gallium nitride layer 71 has a length of l_{oy1}=4 μm and a width of lₒₓ₁=2 μm. The portion of the ohmic metal pillar 73 wrapped by the second gate metal layer 72 has a length of l_{oy2}=4 μm and a width of lₒₓ₂=2 μm.

Optionally, vias 9 are etched in the dielectric layer 8 located between the source ohmic metal layer 5 and the source field plate metal layer 6, between the drain ohmic metal layer 6 and the drain field plate metal layer 61, and between the ohmic metal pillar 73 and the drain field plate metal layer 61.The source ohmic metal layer 5 connects to the source field plate metal layer 51 through metal deposited in the vias 9 on the source ohmic metal layer 5. The drain ohmic metal layer 6 connects to the drain field plate metal layer 61 through metal deposited in the vias 9 on the drain ohmic metal layer 6. The ohmic metal pillar 73 connects to the drain field plate metal layer 61 through metal deposited in the vias 9 on the ohmic metal pillar 73. Exemplarily, in embodiments of the present disclosure, each via 9 has a length of 0.5 μm in a longitudinal direction, and has a length in the first direction Y and a width in the second direction X of 1 μm. The distance between the outer edge of each via 9 located at the top of the ohmic metal pillar 73 and the outer edge of the top of the ohmic metal pillar 73 is at least 0.5 μm. The distance between the outer edge of each via 9 located at the top of the source ohmic metal layer 5 and the edge of the source ohmic metal layer 5 is at least 0.5 μm. The distance between the outer edge of each via 9 located at the top of the drain ohmic metal layer 6 and the edge of the drain ohmic metal layer 6 is at least 0.5 μm.

Preferably, in embodiments of the present disclosure, the gate P-type gallium nitride layer 4 has a width in the second direction X of 2 μm and a length in the first direction Y of 40 μm. The width and length of the first gate metal layer 41 are equal to the width and length of the gate P-type gallium nitride layer 4. The gate P-type gallium nitride layer 4 has a thickness in the longitudinal direction Z of 100 nm, and the first gate metal layer 41 has a thickness of 0.8 μm.

Preferably, in embodiments of the present disclosure, the spacing between the gate P-type gallium nitride layer 4 and the source ohmic metal layer 5 is 2 μm, and the spacing L_{GD} between the gate P-type gallium nitride layer 4 and the drain ohmic metal layer 6 is 20 μm.

Preferably, in embodiments of the present disclosure, both the source ohmic metal layer 5 and the drain ohmic metal layer 6 have a length Wₒ in the first direction Y of 40 μm, a width in the second direction X of 3 μm, and a thickness in the longitudinal direction of 1 μm.

Preferably, the source field plate metal layer 51 and the drain field plate metal layer 61 have a thickness in the longitudinal direction Z of 1 μm and a length in the first direction Y of 40 μm. The source field plate metal layer 51 has a width in the second direction X of 13 μm, the left side of the source field plate metal layer 51 is flush with the left side of the source ohmic metal layer 5, and the right side of the source field plate metal layer 51 is 10 μm away from the right side of the source ohmic metal layer 5. The drain field plate metal layer 61 has a width of 15 μm in the second direction X, the right side of the drain field plate metal layer 61 are flush with the right side of the drain ohmic metal layer 6, and the left side of the drain field plate metal layer 61 is 12 μm away from the left side of the drain ohmic metal layer 6. The distance between the source field plate metal layer 51 and the drain field plate metal layer 61 is 2 μm.

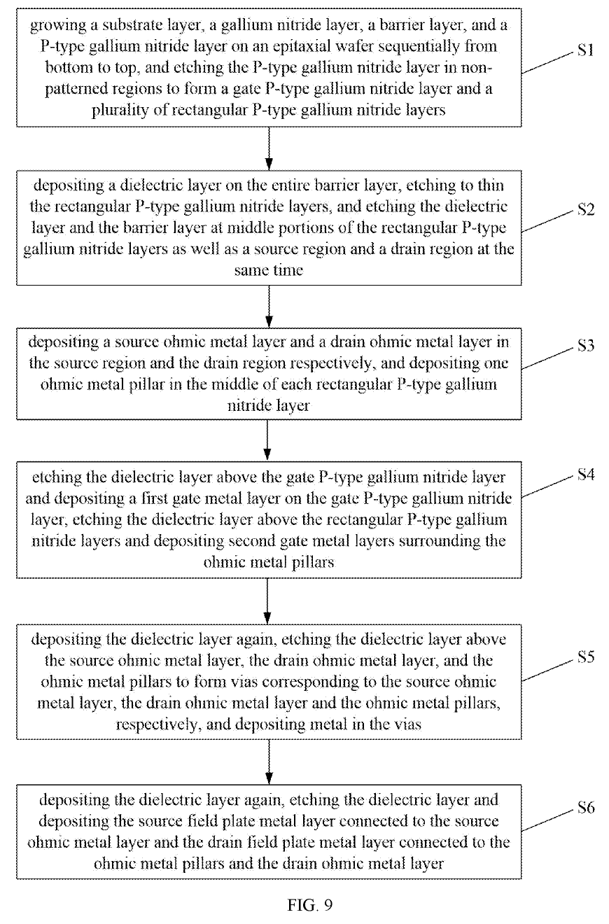

As shown in FIG. 9, embodiments of the present disclosure further provide a preparation method for manufacturing the gallium nitride-based device as shown in FIGS. 2-8, including the following steps:

S1. growing a substrate layer 1, a gallium nitride layer 2, a barrier layer 3, and a P-type gallium nitride layer on an epitaxial wafer sequentially from bottom to top, and etching the P-type gallium nitride layer in non-patterned regions to form a gate P-type gallium nitride layer 4 and a plurality of rectangular P-type gallium nitride layers 71.

Specifically, first, a silicon substrate layer 1 having a thickness of 0.65 mm, a gallium nitride layer 2 having a thickness of 2 μm, a barrier layer 3 having a thickness of 20 nm, and a P-type gallium nitride layer having a thickness of 100 nm grow on an epitaxial wafer sequentially from bottom to top. The P-type gallium nitride layer in non-patterned regions are then etched by an inductively coupled plasma dry etching method to form a plurality of rectangular P-type gallium nitride layers 71 and a long-strip-shaped gate P-type gallium nitride layer 4 extending along the first direction Y. The rectangular P-type gallium nitride layers 71 are located at a side near the drain of the device.

S2. depositing a dielectric layer 8 on the entire barrier layer 3, etching to thin the rectangular P-type gallium nitride layers 71, and etching the dielectric layer 8 and the barrier layer 3 at middle portions of the rectangular P-type gallium nitride layers 71 as well as a source region and a drain region at the same time.

Specifically, the dielectric layer 8 is grown on the entire epitaxial wafer by a plasma enhanced chemical vapor deposition method, and the rectangular P-type gallium nitride layers 71 are thinned by etching through the inductively coupled plasma dry etching method. Then, the dielectric layer 8 is grown again, the dielectric layer 8 and the barrier layer 3 at the middle portion of the rectangular P-type gallium nitride layer 71 as well as the source region and the drain region are etched by the inductively coupled plasma dry etching method so that the rectangular P-type gallium nitride layers 71 can be processed into structures having openings connected to the gallium nitride layer 2 at the middle portions and having a rectangular annular shape as a whole. The source region and the drain region refer to preset regions located at both sides of the gate P-type gallium nitride layer 4 for arranging the source structure and drain structure of the device.

S3. depositing a source ohmic metal layer 5 and a drain ohmic metal layer 6 in the source region and the drain region respectively, and depositing an ohmic metal pillar 73 in the middle of each rectangular P-type gallium nitride layer 71.

Specifically, metal layers consists of Ti/Al (300 nm/700 nm) are sequentially deposited in the source region, the drain region and an opening region at the middle portion of each rectangular P-type gallium nitride layer 71 to form the source ohmic metal layer 5 and the drain ohmic metal layer 6 in the source region and the drain region respectively, and form one ohmic metal pillar 73 in the opening region. The source ohmic metal layer 5, the drain ohmic metal layer 6, and the ohmic metal pillars 73 are all in contact with a top surface of the gallium nitride layer 2.

S4. etching the dielectric layer 8 above the gate P-type gallium nitride layer 4 and depositing the first gate metal layer 41 on the gate P-type gallium nitride layer 4, and etching the dielectric layer 8 above the rectangular P-type gallium nitride layers 71 and depositing second gate metal layers 72 surrounding the ohmic metal pillars 73.

Specifically, the dielectric layer 8 is grown again on an entire epitaxial wafer, the dielectric layer 8 above both the gate P-type gallium nitride layer 4 and the rectangular P-type gallium nitride layers 71 is etched by the inductively coupled plasma dry etching method and a photoetching stripping method, and gate metal made of Ni/Al (300 nm/500 nm) is sequentially deposited to form the first gate metal layer 41 also in a strip shape and the second gate metal layer 72 surrounding the ohmic metal pillar 73 also of a structure in a rectangular annular shape.

S5. depositing the dielectric layer 8 again, etching the dielectric layer 8 above the source ohmic metal layer 5, the drain ohmic metal layer 6, and the ohmic metal pillars 73 to form vias 9 corresponding to the source ohmic metal layer 5, the drain ohmic metal layer 6, and the ohmic metal pillars 73, respectively, and depositing metal in the vias 9.

Specifically, the dielectric layer 8 is grown again on an entire epitaxial wafer, the dielectric layer 8 above the source ohmic metal layer 5, the drain ohmic metal layer 6, and the ohmic metal pillars 73 are etched by the inductively coupled plasma dry etching method and the photoetching stripping method to form a plurality of vias 9, and tungsten metal is deposited in each via 9 to form a component connected to a field plate structure on the top of the device.

S6. depositing the dielectric layer 8 again, etching the dielectric layer 8 and depositing a source field plate metal layer 51 connected to the source ohmic metal layer 5 and a drain field plate metal layer 61 connected to the ohmic metal pillars 73 and the drain ohmic metal layer 6.

Specifically, the dielectric layer 8 is deposited again. The dielectric layer 8 above the vias 9 is etched by the photoetching stripping method. The source field plate metal layer 51 and the drain field plate metal layer 61 are deposited above the vias 9 to complete the preparation of a transistor core portion of the gallium nitride-based device. Specifically, the source ohmic metal layer 5 is connected to the source field plate metal layer 51 via the tungsten metal deposited in the vias 9 on the source ohmic metal layer 5. The ohmic metal pillars 73 and the drain ohmic metal layer 6 are connected to the drain field plate metal layer 61 via the tungsten metal deposited in the vias 9 on the ohmic metal pillars 73 and the drain ohmic metal layer 6.

Compared to the conventional gallium nitride high-electron-mobility transistor structure, in the gallium nitride- based device prepared by the above-mentioned method, a plurality of hole injection structures 7 are provided between the gate P-type gallium nitride layer 4 acted as a gate structure and the drain ohmic metal layer 6 acted as a drain structure, and each hole injection structure 7 consists of a rectangular P-type gallium nitride layer 71, a second gate metal layer 72, and an ohmic metal pillar 73. When bias voltage is applied to the drain, holes are injected into the barrier layer 3 and the gallium nitride layer 2 through the rectangular P-type gallium nitride layers 71, and the injected holes can effectively release electrons trapped by traps near the drains through carrier recombination and other approaches, thereby solving the problems of current collapse and dynamic on-resistance degradation of the device. Further, bottom surfaces of the ohmic metal pillars 73 surrounding the rectangular P-type gallium nitride layers 71 and the second gate metal layers 72 are in contact with the gallium nitride layer 2, such that a gate-to-drain distance of the device is reduced, which balances the problem of current reduction caused by disposing the rectangular P-type gallium nitride layers 71 on a side close to the drain of the device to some extend and attenuates effects of the rectangular P-type gallium nitride layers on two-dimensional electron gas concentration in channels of the device. In addition, the device is simple to manufacture, the hole injection structures 7 grow simultaneously with gate, source, and drain structures of the device, so that compatibility with existing processes can be achieved, the problems like current collapse and dynamic on-resistance degradation caused by hot electron effects under hard switching conditions are solved on the premise of not affecting the normal operations of the device, and the reliability of the device for long-term operations is effectively improved.

Unless otherwise defined, technical or scientific terms used herein shall have the ordinary meaning as understood by those of ordinary skill in the art to which the present disclosure belongs. "First", "second", and similar words used in the specification and claims of the patent application of the present disclosure do not denote any order, quantity, or importance, but rather are merely used for distinguishing between different components. Similarly, "a", or "an", and similar words do not denote a limitation of quantity, but rather denote the presence of at least one. "include", or "include", and similar words means that elements or items present in front of "include" or "include" encompass elements or items and their equivalents listed after "include" or "include", and do not exclude other elements or items. "Connect", or "connecting", and similar words are not restricted to physical or mechanical connection, but can include electrical connection, whether direct or indirect. "Up", "down", "left", "right", and similar words are merely used for indicating relative positional relationships, which may also change accordingly when the absolute position of the object being described changes.

The above descriptions are only for the optional embodiments of the present disclosure and are not intended to limit the present disclosure, and any modification, equivalent, improvement, etc. within the spirit and principles of the present disclosure are intended to be included within the scope of protection of the present disclosure.

What is claimed is:

1. A gallium nitride-based device, comprising a substrate layer, a gallium nitride layer, and a barrier layer that are arranged from bottom to top, wherein a gate P-type gallium nitride layer is provided on the barrier layer, the gate P-type gallium nitride layer is strip-shaped and extends along a first direction, a first gate metal layer is provided on the gate P-type gallium nitride layer, two sides of the gate P-type gallium nitride layer are provided with a source ohmic metal layer and a drain ohmic metal layer respectively, the source ohmic metal layer and the drain ohmic metal layer are connected to the gallium nitride layer, a source field plate metal layer is disposed above and connected to the source ohmic metal layer, a drain field plate metal layer is disposed above and connected to the drain ohmic metal layer, hole injection structures are disposed between the gate P-type gallium nitride layer and the drain ohmic metal layer, each hole injection structure comprises a rectangular P-type gallium nitride layer, a second gate metal layer and an ohmic metal pillar, the rectangular P-type gallium nitride layer and the second gate metal layer are disposed on the barrier layer from bottom to top, the ohmic metal pillar passes through middle portions of the rectangular P-type gallium nitride layer and the second gate metal layer and connects to the gallium nitride layer, a top of the ohmic metal pillar is connected to the drain field plate metal layer, a region between the barrier layer and the source field plate metal layer and a region between the barrier layer and the drain field plate metal layer are filled with a dielectric layer.

2. The gallium nitride-based device according to claim 1, wherein a plurality of hole injection structures are provided and arranged at intervals along the first direction.

3. The gallium nitride-based device according to claim 2, wherein in a second direction perpendicular to the first direction, rectangular P-type gallium nitride layers in at least two of the hole injection structures have different widths.

4. The gallium nitride-based device according to claim 3, wherein in the second direction, a width of each second gate metal layer in the plurality of hole injection structures varies with a width of the rectangular P-type gallium nitride layer therebeneath.

5. The gallium nitride-based device according to claim 1, wherein the second gate metal layer and the rectangular P-type gallium nitride layer each have an internal hole in a middle portion thereof for the ohmic metal pillar to pass through, and a size of the internal hole in the second gate metal layer is smaller than or equal to that of the internal hole in the rectangular P-type gallium nitride layer.

6. The gallium nitride-based device according to claim 1, wherein the ohmic metal pillar, the source ohmic metal layer, and the drain ohmic metal layer have equal heights.

7. The gallium nitride-based device according to claim 1, wherein a cross-sectional profile of the ohmic metal pillar is square, circular, or irregular.

8. The gallium nitride-based device according to claim 1, wherein vias are etched in the dielectric layer located between the source ohmic metal layer and the source field plate metal layer, between the drain ohmic metal layer and the drain field plate metal layer, and between the ohmic metal pillar and the drain field plate metal layer; connections between the source ohmic metal layer and the source field plate metal layer, between the drain ohmic metal layer and the drain field plate metal layer, and between the ohmic metal pillar and the drain field plate metal layer are formed by metal deposited in the vias.
